(19) United States
(12) Patent Application Publication
(10) Pub. No.: US 2019/0352543 A1
(43) Pub. Date: Nov. 21, 2019

(54) COMPOSITE COMPOSITIONS FOR ELECTROMAGNETIC INTERFERENCE SHIELDING AND ARTICLES INCLUDING THE SAME

(71) Applicant: 3M INNOVATIVE PROPERTIES COMPANY, St. Paul, MN (US)

(72) Inventors: Dipankar Ghosh, Oakdale, MN (US); Jitendra S. Rathore, Woodbury, MN (US)

(21) Appl. No.: 16/479,509

(22) PCT Filed: Feb. 7, 2018
(86) PCT No.: PCT/IB2018/050760

§ 371 Date: Jul. 19, 2019

Related U.S. Application Data
(60) Provisional application No. 62/458,796, filed on Feb. 14, 2017.

(51) Int. Cl. C09J 11/04; C09J 11/08; C09J 7/26; C09J 7/38; H05K 9/00; H01L 23/552

(52) U.S. Cl. CPC C09J 11/04; C09J 11/08; C09J 7/26; C09J 7/38; H05K 9/0083; C09J 2203/326; H01L 23/552; C09J 2400/243; C09J 2483/006; C09J 2205/106; H05K 9/0098

(57) ABSTRACT

An electronic article comprises an electronic component bonded to a composite composition. The composite composition comprises a crosslinked silicone foam having polydimethylsiloxane segments, and electromagnetically responsive particles retained in the crosslinked silicone foam. Composite compositions comprising carbon nanotubes and electromagnetic wave shielding articles including them are also disclosed.

### TECHNICAL FIELD

The present disclosure relates to composites and articles for high frequency electromagnetic interference (EMI) shielding applications and methods of making the same.

### BACKGROUND

Electronic devices, such as those found in computers, microprocessors, calculators, watches, radios, televisions, mobile phones, vehicle ignition systems, word processors, and the like, are often sensitive to electromagnetic interference (EMI). The EMI may originate from a variety of sources, including in many cases the electrical sources and electronic devices themselves. Radio, television, and other communication systems are also sources of EMI, which can disrupt the functioning of the electronic devices, causing diminished performance or even device failure. The problem becomes increasingly more pronounced as active circuits shrink in size and are positioned closer together and also as devices work at higher frequency levels.

To ensure normal operation of the electronic devices, it is desirable and sometimes necessary to block, i.e., substantially reduce, the undesired EMI. The blocking may be for the purpose of reducing the amount of EMI radiating outwardly from a given circuit or circuit component, reducing the amount of EMI radiating inwardly towards the circuit or circuit component from other sources, or both. The blocking, also known as shielding, can be achieved by reflection of the EMI, absorption of the EMI, or a combination of both. In one common approach, a metal sheet or foil known as an EM shield, which has high electrical conductivity, is used to reflect the undesired EMI.

Reflecting the EMI may, however, in some cases be insufficient and may cause further problems. Also, eddy currents can reduce the metal's effectiveness as a shielding material at very high frequencies, such as gigahertz (GHz) frequencies. In another approach, materials or structures may be used that predominantly absorb, rather than reflect, the unwanted EMI.

### SUMMARY

One way to mitigate such issues is to use composite materials that have intrinsic porosity. These porous composite materials, or “foamy composites”, have lower values of the real part of dielectric permittivity, and therefore lower values of reflection resulting in increased absorption performance of such composites. These foamy composites are especially useful for EMI control in the 100 MHz-80 GHz frequency range. However, there remains a need for new porous composite materials with at least one of lower cost, ease of manufacture, better EMI shielding performance in the in the 100 MHz-80 GHz frequency range, improved ease of use, reduced size and/or weight, better flexibility, and/or mechanical durability.

In one aspect, the present disclosure provides an electronic article comprising an electronic component bonded to a composite composition, the composite composition comprising: a crosslinked silicone foam, wherein the crosslinked silicone foam has polydimethylsiloxane segments; and electromagnetically responsive particles, wherein the electromagnetically responsive particles are retained in the crosslinked silicone foam. Exemplary electronic components include processors, coprocessors, optical interconnects, memory devices, transistors, resistors, capacitors, inductor, transmission lines, and conductors.

In another aspect, the present disclosure provides a composite composition comprising: a crosslinked silicone foam, wherein the crosslinked silicone foam has polydimethylsiloxane segments; and electromagnetically responsive particles retained in the crosslinked silicone foam, wherein the electromagnetically responsive particles comprise carbon nanotubes. In some preferred embodiments, the carbon nanotubes include crosslinked multiwall carbon nanotube-based networks, more preferably wherein the electromagnetically responsive particles further comprise a polymeric encapsulation material, and wherein the crosslinked multiwall carbon nanotube-based networks are at least partially encapsulated by the polymeric encapsulation material.

In yet another aspect, the present disclosure provides an electromagnetic wave shielding article comprising a composite composition according to the present disclosure secured to a pressure-sensitive adhesive layer. In some preferred embodiments, a backing is disposed between the composite composition and the pressure-sensitive adhesive layer.

Advantageously, compositions and articles in the present disclosure benefit from in-situ and controlled foaming via hydrogen evolution during curing, without the need of an external blowing agent. Moreover, the compositions are readily preparable from commercially available materials. Composite compositions according to the present disclosure reduce reflect loss, and provide thinner/lighter alternatives to known EMI shielding materials.

As used herein:

The term “bonded to” includes both direct and indirect bonding. For example, bonding may be through direct contact, an adhesive layer, or through bonding to an intermediate common structure (e.g., a circuit board).

The term “consisting essentially” in reference to a composite composition means that the composition is free of compounds that materially affect the electromagnetic wave absorbing and reflecting properties.

The terms “polymer” and “polymeric” refer to organic polymers and not to inorganic polymers.

The term “silicone foam” refers to a silicone-based material having pores distributed throughout it.

Features and advantages of the present disclosure will be further understood upon consideration of the detailed description as well as the appended claims.

### BRIEF DESCRIPTION OF THE DRAWINGS

FIG. 1 is a schematic perspective view of exemplary electronic article 100 according to the present disclosure.

FIG. 2 is a schematic perspective view of a portion of a high density connector cable for high speed data transfer applications, where each of the signal conductors is surrounded by an EMI shielding layer.

FIG. 3 is a schematic side view of an electromagnetic wave shielding article 300 according to the present disclosure.

FIG. 4 is a plot of power vs. electromagnetic radiation absorbed for the composite composition of Comparative Example 1 and Example 1.

Repeated use of reference characters in the specification and drawings is intended to represent the same or analogous features or elements of the disclosure. It should be understood that numerous other modifications and embodiments can be devised by those skilled in the art, which fall within the scope and spirit of the principles of the disclosure. The figures may not be drawn to scale.

### DETAILED DESCRIPTION

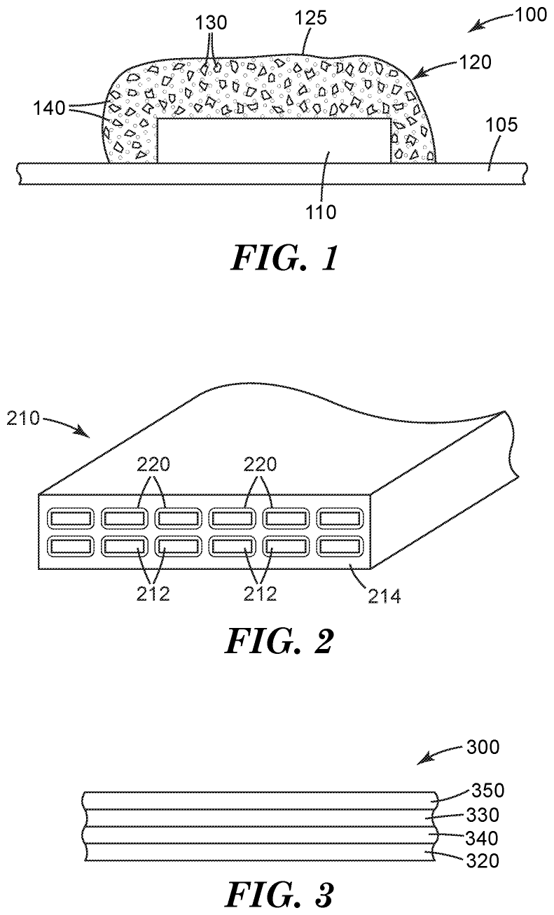

Referring now to FIG. 1, electronic article 100 comprises electronic component 110 on circuit board 105 bonded to a composite composition 120. Composite composition 120 comprises a crosslinked silicone foam 125 having polydimethylsiloxane segments, and has pores 130 distributed throughout. Electromagnetically responsive particles 140 are retained in the crosslinked silicone foam 125.

An exemplary electronic article is shown in FIG. 2. Referring now to FIG. 2, high density connector cable 210, which may, for example, be used as a connector cable for high speed data transfer applications, includes a plurality of metal signal conductors 212 that span the length of the cable 210, the conductors 212 being embedded in, and held in place by, a flexible insulator 214 such as a low dielectric loss polymer. The conductors 212 may be configured as differential pairs for data transfer, or in any other desired way. Although twelve conductors 212 are shown and arranged in two rows of six, fewer or greater than twelve conductors can be used, and they can be arranged in different numbers of rows and columns. In one such alternative embodiment, the cable may have only one conductor, or only two conductors. In order to reduce the influence of EMI on the transmitted signals, and/or to reduce the amount of EMI emitted by the cable 210, each of the conductors 212 is surrounded by EMI shielding layers 220, where it is understood that the shielding layers 220 are made of a composite composition according to the present disclosure. The shielding layers 220 may, for example, be extruded through a die during the fabrication of the cable 210. When viewed in cross-section perpendicular to the length of the cable 210, the shielding layers 220 are shown as completely surrounding their respective conductors 212, but in alternative embodiments a given shielding layer may surround a set of two or more conductors, and in still other embodiments the shielding layers may only partially surround one, two, or more of the conductors. The partial surrounding may be realized, for example, by an EMI shielding layer that, in perpendicular cross-section, spans a given row of two or three conductors or more, but that undulates periodically in a V-shape between adjacent conductors 212 so as to partially surround each conductor.

FIG. 3 shows an exemplary electromagnetic wave shielding article according to the present disclosure. Referring now to FIG. 3, electromagnetic wave shielding article 300 comprises a layer 320 of composite composition according to the present disclosure secured to a pressure-sensitive adhesive layer 330. Optional backing 340 is disposed between layer 320 of composite composition 120 and pressure-sensitive adhesive layer 330. Optional protective release liner 350 is releasably adhered to pressure-sensitive adhesive layer 330. If present, optional backing 340 is preferably flexible, although this is not a requirement.

In some preferred embodiments when the optional backing is present, the optional release liner is not present and the pressure sensitive adhesive is releasably adhered to the composite composition.

Electromagnetic wave shielding articles according to the present disclosure may be used as a tape from which one or more pieces can be cut and adhered to a workpiece such as a circuit, circuit component, or enclosure containing such a circuit or circuit component, for purposes of mitigating EMI, for example.

Examples of electronic components that may be shielded using composite compositions and/or electromagnetic wave shielding articles according to the present disclosure include processors, coprocessors, memory devices, transistors, resistors, capacitors, inductors, transmission lines, antennas, conductors, and combinations thereof.

Composite compositions according to the present disclosure can be applied to an electronic component as a curable composite composition precursor (e.g., using a two-part mixing nozzle), or it can be applied as an adhesive tape or sheet. If desired, a curable composite composition precursor can be molded into a predetermined shape (e.g., a housing and/or protective cover) and cured, then adhesively bonded (using an adhesive) to the electronic component or a supporting structure (e.g., a circuit board).

Various two-part curable silicone compositions (typically known in the art as having a part A composition and a part B composition that cure when mixed) may be used to generate foamy silicone compositions. For example, the part A composition may comprise a monomer, oligomer, or polymer having a plurality of Si—OH functional groups, and part B comprises a silicone monomer, oligomer, or polymer having a plurality of Si—H functional groups. Once the parts are combined and a catalyst is present (separately added or contained in part A or part B), dehydrogenative condensation of a silanol group with a silyl hydride group forming hydrogen gas in a crosslinked silicone matrix, thereby resulting in entrapped bubbles. If the electromagnetically responsive particles are mixed into part A or part B or their combined mixture, then on curing a composite composition is obtained that comprises a crosslinked silicone foam having polydimethylsiloxane segments, and has pores distributed throughout. Electromagnetically responsive particles are retained in the crosslinked silicone foam. Depending on the curable silicone compositions used, foam with open cell structure, closed cell structure, or a combination of open and closed cell structure may be obtained.

Exemplary compounds suitable for use as part A in forming curable silicone compositions include silicone oligomers and polymers having at least one polydimethylsiloxane segment and at least two Si—OH hydroxysilyl groups. Preferably, the silicone oligomers and polymers are polymers, which can be linear, branched, or cyclic.

The molecular weight and the reactive silane functionality of part A (including the number and nature of the hydroxysilyl groups) can vary widely, depending upon, for example, the molecular weight and the Si—H functionality of part B and the properties desired for the curable and/or cured composition. Generally, at least one of parts A or B has an average reactive silane functionality of at least three (that is, part A has at least three hydroxysilyl groups (on average), part B has at least three hydrosilyl moieties (on average), or both), however, so as to enable the formation of a crosslinked network.

In some embodiments, silicone monomers, oligomers, or polymers having a plurality of Si—H functional groups used for part A are hydroxyl-terminated, so as to comprise two terminal hydroxysilyl moieties (on average). The polysiloxanes preferably have a weight average molecular weight of about 150 to about 1,000,000 (more preferably, about 1,000 to about 1,000,000) g/mol.

A preferred class of useful polyorganosiloxanes includes those that can be represented by general formula I, below:

(OH)ₚ—Si(CH₃)₃₋ₚ-[G-Si(CH₃)₂]ₜ—O—[(CH₃)₂SiO]_{q}[Si(CH₃)₂-G]ₜ—Si(CH₃)₃₋ₚ—(OH)ₚ (I)

wherein each p is independently an integer of 1, 2, or 3 (preferably, 1); each G is independently a divalent linking group; q is an integer of 0 to about 15,000 (preferably, about 20 to about 15,000); and each t is independently an integer of 0 or 1 (preferably, 0). Each divalent linking group, G, is preferably independently selected from oxy, alkylene, arylene, heteroalkylene, heteroarylene, cycloalkylene, heterocycloalkylene, and combinations thereof (more preferably, selected from oxy, alkylene, arylene, and combinations thereof). Heteroatoms (in G) can include oxygen, sulfur, nitrogen, phosphorus, and combinations thereof (preferably, oxygen, sulfur, and combinations thereof; more preferably, oxygen). G can contain fluorine, provided that it is separated from silicon by at least two carbon atoms.

Preferred polysiloxanes include hydroxyl-terminated polydimethylsiloxane homopolymer, as well as hydroxyl-terminated copolymers comprising dimethylsiloxane units and up to about 40 or 50 mole percent of other units selected from dialkylsiloxane units, (alkyl)(methyl)siloxane units, and (alkyl)(phenyl)siloxane units wherein each alkyl group is independently selected from alkyl groups having two to about 8 carbon atoms (for example, hexyl), di(fluoroalkyl)siloxane units, (fluoroalkyl)(methyl)siloxane units, and (fluoroalkyl)(phenyl)siloxane units wherein each fluoroalkyl group is independently selected from fluoroalkyl groups having 3 to about 8 carbon atoms (for example, trifluoropropyl or nonafluorohexyl), diphenylsiloxane units, and combinations thereof.

The polyorganosiloxanes useful as part A can be used alone of as a combination of two or more polyorganosiloxanes.

Polyorganosiloxanes suitable for use as part A can be prepared by known synthetic methods and many are commercially available. For example, the hydroxysilyl-functional components of SYL-OFF 292 coating composition (available from Dow Corning Corporation, Midland, Mich.) are preferred polysiloxanes, and other useful polysiloxanes of varying molecular weight can be obtained from Gelest, Inc., Morrisville, Pa. (see, for example, the polysiloxanes described in Silicon Compounds: Silanes and Silicones, Second Edition, edited by B. Arkles and G. Larson, Gelest, Inc. (2008)).

Exemplary compounds suitable for use as part B in forming curable silicone compositions include silicone oligomers and polymers having at least one polydimethylsiloxane segment and at least two Si—H hydroxysilyl groups. Preferably, the silicone oligomers and polymers are polymers, which can be linear, branched, or cyclic.

Polysiloxanes suitable for use as part B of the curable compositions of the invention include polyorganosiloxanes, fluorinated polyorganosiloxanes, and combinations thereof (preferably, polyorganosiloxanes; more preferably, polyalkyl(hydro)siloxanes) comprising reactive silane functionality comprising at least two hydrosilyl moieties (that is, monovalent moieties comprising a hydrogen atom bonded directly to a silicon atom). The polysiloxanes can be small molecules, oligomers, polymers, or a combination thereof. Preferably, the polysiloxanes are polymers. The polysiloxanes can be linear, branched, or cyclic. Useful polymers include those that have random, alternating, block, or graft structures, or a combination thereof.

The molecular weight and the reactive silane functionality of part B (including the number and nature of the Si—H groups) can vary widely, depending upon, for example, the molecular weight and the reactive silane functionality of part A and the properties desired for the curable and/or cured composition. Preferably, part B has an average reactive silane functionality of at least three (so as to enable the formation of a crosslinked network when part A is hydroxyl-terminated). The polysiloxanes preferably have a weight average molecular weight of about 100 to about 100,000 g/mol.

A preferred class of polysiloxanes useful in part B includes those that can be represented by general formula II, below:

R′₂R″SiO(R₂SiO)ᵣ(HR′SiO)ₛSiR″R′₂ (II)

wherein each R′ is independently selected from alkyl, alkenyl, fluoroalkyl, aryl, fluoroaryl, cycloalkyl, fluorocycloalkyl, heteroalkyl, heterofluoroalkyl, heteroaryl, heterofluoroaryl, heterocycloalkyl, heterofluorocycloalkyl, and combinations thereof; each R″ is independently hydrogen (hydro) or R′; r is an integer of 0 to about 150 (preferably, 0 to about 100; more preferably, 0 to about 20); and s is an integer of 2 to about 150 (preferably, about 5 to about 100; more preferably, about 20 to about 80). Most preferably, both R″ and R′ are methyl, r is 0, and/or s is about 40.

Preferred hydride-functional polysiloxanes include those comprising polymethyl(hydro)siloxane homopolymer, as well as those comprising copolymer(s) comprising methyl(hydro)siloxane units and up to about 40 or 50 mole percent of other units selected from dialkylsiloxane units, (alkyl)(methyl)siloxane units, and (alkyl)(phenyl)siloxane units wherein each alkyl group is independently selected from alkyl groups having two to about 8 carbon atoms (for example, hexyl), di(fluoroalkyl)siloxane units, (fluoroalkyl)(methyl)siloxane units, and (fluoroalkyl)(phenyl)siloxane units wherein each fluoroalkyl group is independently selected from fluoroalkyl groups having 3 to about 8 carbon atoms (for example, trifluoropropyl or nonafluorohexyl), diphenylsiloxane units, and combinations thereof. Although homopolymer is often preferred, copolymers can be preferred for some applications.

Polysiloxanes useful as part B can be used in the curable compositions of the invention singly or in the form of mixtures of different polysiloxanes. The polysiloxanes can be prepared by known synthetic methods and many are commercially available. For example, SYL-OFF Q2-7560 crosslinker, SYL-OFF 7678 crosslinker, and the hydrosilyl-functional component (for example, SYL-OFF 7048 crosslinker) of SYL-OFF 292 and SYL-OFF 294 coating compositions (all available from Dow Corning Corporation, Midland, Mich.) are preferred polysiloxanes, and other useful polysiloxane crosslinkers of varying molecular weight can be obtained from Gelest, Inc., Morrisville, Pa. (see, for example, the polysiloxanes described in Silicon Compounds: Silanes and Silicones, Second Edition, edited by B. Arkles and G. Larson, Gelest, Inc. (2008)).

Curable composite composition precursors (e.g., two-part silicone compositions) useful for preparing composite compositions according to the present disclosure preferably comprise a catalyst for dehydrogenative condensation of a silanol group with a silyl hydride group with formation of hydrogen gas. Generally residue of the catalyst is present in the resultant cured composite composition. Organic solvent may be included in curable composite composition precursors useful for preparing the composite compositions.

Catalysts for dehydrogenative condensation of a silanol group with a silyl hydride group with formation of hydrogen gas are known in the art. Many suitable catalysts are complexes of a precious metal such as, for example, platinum, rhodium, iridium, or palladium. Examples of suitable catalysts include chloroplatinic acid; RhCl₃[(C₈H₁₇)S]₃ and (RhCl₃[(C₈H₁₇)₂]₃) as described in U.S. Pat. No. 4,262,107 (Eckberg); Karstedt's catalyst; IrCl(CO)(TPP)₂, Ir(CO)₂(acac), IrHC₁₂(TPP)₃, [IrCl(cyclooctene)₂]₂, IrI(CO)(TPP)₂, and IrH(CO)(TPP)₃, in which formulae TPP signifies a triphenylphosphine group and acac signifies an acetylacetonate group; certain amines; colloidal nickel; dibutyltin dilaurate; and carbene-type catalysts as described in U.S. Pat. No. 9,150,755 B2 (Maliverney).

The use of such a catalyst makes it possible to efficiently catalyze the dehydrogenative condensation reaction between Si—H and Si—OH siloxane groups to form Si—O—Si linkages and H₂ under mild temperature conditions, generally at temperatures of less than 150° C., typically less than 100° C., and commonly at ambient temperature. Silicone networks or polymers can thus be obtained in a few minutes.

The concentration of the catalyst(s) present is typically between 0.01 and 5 weight percent, preferably between 0.05 and 1 weight percent, based on the total weight of curable composite composition precursor, although this is not a requirement.

The porosity of composite compositions according to the present disclosure is preferably at least 10 percent, at least 20 percent, at least 30 percent, or even at least 35 percent by volume up to 40 percent, up to 50 percent, up to 60 percent, or even up to 70 percent by volume, although other values may also be used.

Examples of useful electromagnetically responsive (e.g., conductive) particles include metal particles, metal alloy particles, carbon fibers, carbon bubbles and carbon foams, carbon nanotubes, metal nanoparticles, metal nanowires, graphite, graphene-based materials (including exfoliated graphite nanoplatelets, doped and undoped graphene, graphene nanoplatelets, reduced graphene oxide, functionalized graphene sheets, and combinations thereof), carbon nanotubes (e.g., single-wall carbon nanotubes, multi-wall carbon nanotubes, and crosslinked multi-wall carbon nanotube networks), and insulating particles with conductive coatings such as metal-coated glass bubbles. Of these, carbon nanotubes are preferred, and crosslinked multi-wall carbon nanotube networks are especially preferred in some embodiments. One exemplary commercial electromagnetically responsive material that can be ground into fine powder is CNS encapsulated flakes from Applied NanoStructured Solutions LLC, Baltimore, Md., which are polymer-encapsulated crosslinked multiwall carbon nanotube networks.

The electromagnetically responsive particles are typically present in no less than 5%, 10%, 15%, 20%, 30%, or 40% by weight or by volume of the composite composition, and no more than about 70%, 80%, 90%, 100%, 125%, 150%, 175%, 200%, 225%, or 250% by weight or volume of the composite composition. However, other amounts can also be used depending on the application desired.

The electromagnetically responsive particles preferably have an average size less than 5 microns, less than 1 micron, or even less than 0.1 micron; however, other average sizes may also be used.

The electromagnetically responsive particles and/or catalyst can be added to a curable composite composition precursor before, after, or while mixing the other components (e.g., part A and part B). Suitable variations in addition protocol will be apparent to those of skill in the art.

Composite compositions according to the present disclosure may optionally include inorganic domains that can impart hardness. These inorganic domains may result from addition of inorganic oxide particles (which may include nanoparticles) to a curable composition precursor (e.g., a two-part curable silicone). In such cases, the domains are generally at least as large as a single inorganic particle. Suitable particles of the present disclosure include an inorganic oxide and may have an average particle size up to about 1 micron, although large inorganic oxide particles may also be used. In some preferred embodiments, the inorganic oxide particles are nanoparticles, although this is not a requirement. As used herein, the term “nanoparticles” refers to particles having an average size of less than or equal to about 0.1 micron.

Exemplary inorganic oxide particles can include an oxide of a non-metal, an oxide of a metal, or a combination thereof. An oxide of a non-metal includes an oxide of, for example, silicon or germanium. An oxide of a metal includes an oxide of, for example, iron, titanium, cerium, aluminum, zirconium, vanadium, zinc, antimony, and tin. A combination of a metal and non-metal oxide includes an oxide of aluminum and silicon.

In some preferred embodiments, the inorganic particles comprise silica. In some preferred embodiments the inorganic particles comprise TiO (i.e., titanium monoxide) and CuO (Cupric oxide) particles.

The inorganic nanoparticles can have an average particle size of no greater than 100 nanometers (nm), no greater than 75 nanometers, no greater than 50 nanometers, no greater than 25 nanometers, no greater than 20 nanometers, no greater than 15 nanometers, or no greater than 10 nanometers. The inorganic nanoparticles can have an average particle size of at least 1 nanometer, at least 5 nanometers, at least 15 nanometers, at least 20 nanometers, at least 25 nanometers, at least 50 nanometers, or at least 75 nanometers.

Various inorganic oxide particles are commercially available. Commercial sources of inorganic oxide particles (including inorganic nanoparticles) include, for example: Nyacol Co., Ashland, Mass.; Solvay-Rhodia, Lyon, France, and Nalco Co., Naperville, Ill.

Nanoparticles can also be made using techniques known in the art. For example, zirconia nanoparticles can be prepared using hydrothermal technology, as described for example in PCT Publication No. WO2009/085926 (Kolb et al.). Suitable zirconia nanoparticles are also those described in, for example, U.S. Pat. No. 7,241,437 (Davidson, et al.).

In some embodiments, the inorganic nanoparticles may be in the form of a colloidal dispersion. Colloidal silica nanoparticles in a polar solvent are particularly desirable. Silica sols in a polar solvent such as isopropanol are available commercially under the trade names ORGANOSILICASOL IPA-ST-ZL, ORGANOSILICASOL IPA-ST-L, and ORGANOSILICASOL IPA-ST from Nissan Chemical Industries, Ltd., Chiyoda-Ku Tokyo, Japan. Preferably, the nanoparticles are dispersed in a curable composition of the present disclosure.

If present, the optional inorganic oxide particles are typically present in the composite composition in an amount of at least 5 weight percent, at least 10 weight percent, or even at least 15 weight percent up to at least 25 weight percent, or even 50 weight percent, based on the total weight of the composite composition; however, other amounts may also be used. If present, inorganic oxide particles are typically present in the composite composition in an amount of no greater than 50 weight percent, or no greater than 30 weight percent, based on the total weight of the composition.

Composite compositions useful in practice of the present disclosure may, for example, have a loss tangent, such as a dielectric loss tangent, a magnetic loss tangent, or both, of at least 0.03, or at least 0.1, or at least 0.3, or at least 0.4 over a frequency range from 1 GHz to 5 GHz. A component of the loss tangent due to the optional inorganic particles may be at least 0.01, or at least 0.05, or at least 0.1 over such frequency range. Dielectric loss tangent is a measure of how much a material absorbs or dissipates electromagnetic radiation.

The composite composition may optionally include one or more non-silicone polymers; however, this is typically not desirable. Exemplary non-silicone polymers include halogenated polymers, acrylic polymers, polyether polymers, polyurethanes, and combinations thereof.

The composite composition may optionally further include various additives such as rheology modifiers, colorants, antioxidants, light stabilizers, plasticizers, and fillers, for example.

### Select Embodiments of the Present Disclosure

In a first embodiment, the present disclosure provides an electronic article comprising an electronic component bonded to a composite composition, the composite composition comprising: a crosslinked silicone foam, wherein the crosslinked silicone foam has polydimethylsiloxane segments; and electromagnetically responsive particles, wherein the electromagnetically responsive particles are retained in the crosslinked silicone foam.

In a second embodiment, the present disclosure provides an electronic article according to the first embodiment, wherein the electromagnetically responsive particles comprise at least one of carbon black, carbon bubbles, carbon foams, carbon fibers, carbon nanotubes, exfoliated graphite, graphene, metal particles, metal alloy particles, or metal-coated composite particles.

In a third embodiment, the present disclosure provides an electronic article according to the first embodiment, wherein the electromagnetically responsive particles comprise carbon nanotubes.

In a fourth embodiment, the present disclosure provides an electronic article according to any one of the third embodiment, wherein the carbon nanotubes comprise crosslinked multiwall carbon nanotube-based networks.

In a fifth embodiment, the present disclosure provides an electronic article according to the fourth embodiment, wherein the electromagnetically responsive particles further comprise a polymeric encapsulation material, and wherein the crosslinked multiwall carbon nanotube-based networks are at least partially encapsulated by the polymeric encapsulation material.

In a sixth embodiment, the present disclosure provides an electronic article according to any one of the first to fifth embodiments, wherein the electronic component comprises at least one of a processor, coprocessor, memory device, transistor, transmission line, optical interconnects or conductor.

In a seventh embodiment, the present disclosure provides an electronic article according to any one of the first to sixth embodiments, wherein the crosslinked silicone foam further comprises a precious metal.

In an eighth embodiment, the present disclosure provides an electronic article according to any one of the first to seventh embodiments, wherein the composite composition consists essentially of the crosslinked silicone foam and the electromagnetically responsive particles.

In a ninth embodiment, the present disclosure provides an electronic article according to any one of the first to eighth embodiments, wherein the crosslinked silicone foam comprises a closed cell foam.

In a tenth embodiment, the present disclosure provides an electronic article according to any one of the first to ninth embodiments, wherein the composite composition is capable of absorbing at least a portion of incoming electromagnetic energy in a frequency range of 0.1 to 40 GHz.

In an eleventh embodiment, the present disclosure provides an electronic article according to any one of the first to tenth embodiments, wherein the composite composition further comprises inorganic oxide particles.

In a twelfth embodiment, the present disclosure provides an electronic article according to any one of the first to tenth embodiments, wherein the composite composition is free of inorganic oxide particles.

In a thirteenth embodiment, the present disclosure provides a composite composition comprising:

a crosslinked silicone foam, wherein the crosslinked silicone foam has polydimethylsiloxane segments; and

electromagnetically responsive particles retained in the crosslinked silicone foam, wherein the electromagnetically responsive particles comprise carbon nanotubes.

In a fourteenth embodiment, the present disclosure provides a composite composition according to the thirteenth embodiment, wherein the carbon nanotubes include crosslinked multiwall carbon nanotube-based networks.

In a fifteenth embodiment, the present disclosure provides a composite composition according to the fourteenth embodiment, wherein the crosslinked multiwall carbon nanotube-based networks are at least partially encapsulated by a polymeric encapsulation material.

In a sixteenth embodiment, the present disclosure provides a composite composition according to any one of the thirteenth to fifteenth embodiments, wherein the composite composition is capable of absorbing at least a portion of incoming electromagnetic energy in a frequency range of 0.1 to 40 GHz.

In a seventeenth embodiment, the present disclosure provides a composite composition according to any one of the thirteenth to sixteenth embodiments, wherein the composite composition comprises inorganic oxide particles.

In an eighteenth embodiment, the present disclosure provides a composite composition according to any one of the thirteenth to seventeenth embodiments, wherein the composite composition is molded according to a predetermined shape.

In a nineteenth embodiment, the present disclosure provides a composite composition according to any one of the thirteenth to eighteenth embodiments secured to a pressure-sensitive adhesive layer.

In a twentieth embodiment, the present disclosure provides an electromagnetic wave shielding article according to the nineteenth embodiment, further comprising a backing disposed between the composite composition and the pressure-sensitive adhesive layer.

Objects and advantages of this disclosure are further illustrated by the following non-limiting examples, but the particular materials and amounts thereof recited in these examples, as well as other conditions and details, should not be construed to unduly limit this disclosure.

### EXAMPLES

Unless otherwise noted, all parts, percentages, ratios, etc. in the Examples and the rest of the specification are by weight.

Table 1 provides abbreviations and sources for materials used in the Examples.

TABLE 1

| ABBREVIATION | DESCRIPTION |
|---|---|
| CNS flakes | Encapsulated crosslinked multiwall carbon nanotube |
| | networks (about 70 microns long and 10 microns |
| | thick), available as CNS encapsulated flakes from |
| | Applied NanoStructured Solutions LLC, Baltimore, |
| | Maryland |
| Silanol-terminated | Silanol-terminated polydimethylsiloxane (18,000 cSt |
| PDMS | (0.018 m²/s)), available as DMS-S42; liquid from |
| | Gelest, Morrisville, Pennsylvania |
| CATOL | Highly-active platinum complex, available as |
| | CATALYST OL; liquid from Wacker Chemical |
| | Corporation, Adrian, Michigan |
| SO7678 crosslinker | Liquid crosslinker available as SYL-OFF 7678 from |
| | Dow Corning, Midland, Michigan |
| S184 | Two-part silicone elastomer kit, available as |
| | SYLGARD 184 from Dow Corning |

### Test Methods

The following test methods were used in evaluating Examples.

Micro strip line measurements were performed at room temperature for the silicone composite samples to characterize the power transmission characteristics of the test samples at GHz frequencies. For each test, a silicone composite sample (50 mm×50 mm×˜1 mm) was centered onto a 90 mm×3 mm microstrip (Cu trace) line formed on the front surface of a printed circuit board (PCB FR4 board; 90 mm×77 mm×1.57 mm) substrate having an electrically conductive layer on the back surface. A network analyzer terminal was connected to both ends of the microstrip line; an input signal was supplied from one terminal; an output signal was measured from the other terminal; and the S parameters were measured to calculate the power loss characteristics.

The calculated power loss value (S₂₁) allows the electromagnetic wave suppressing ability of the samples to be evaluated and compared. S parameters were obtained using a ZVA67 Vector Network Analyzer (VNA), from Rohde and Schwarz (Munich, Germany), at room temperature over the frequency range of 1-30 GHz, according to the manufacturer's operating instructions.

### Comparative Example 1

CNS flakes were ground to fine powder using a mortar and pestle under dry conditions at room temperature. The CNS flakes included about 4 wt. % of polyurethane encapsulation material and about 96 wt. % of cross-linked carbon nanostructures.

S184 silicone elastomer kit was prepared in a plastic cup by first placing the required amount of Part A (SYLGARD 184 SILICONE BASE POLYMER) under vacuum for 10-15 minutes to degas the material before adding the required amount of Part B (SYLGARD 184 SILICONE CURING AGENT). To this mixture was added the powdered CNS flakes (1.1 wt. %). The plastic cup was covered with a cap configured to allow speed mixing using a FlackTek Speedmixer (model no. DAC 400.2 VAC-P, Landrum, S.C.) under vacuum (100 mbar) for 2 minutes and 15 seconds. The mixture was then sandwiched between a pair of steel plates with an appropriate steel spacer with a thickness of approximately 1 millimeter (mm). The entire stack was placed into a Carver Laboratory Press (Model No. 3725, Wabash, Ind.). The press was used to apply a \pressure of approximately 3 metric tons at 118° C. for 45-60 minutes. The plates were allowed to cool for 30-45 minutes before the cured silicone composite sheet was removed.

### Example 1

CNS flakes were ground to fine powder using a mortar and pestle under dry conditions at room temperature. The CNS flakes included about 4 wt. % of polyurethane encapsulation material and about 96 wt. % of cross-linked carbon nanostructures.

In a cup, 10 grams (g) of silanol-terminated PDMS, one drop of CATOL, and 0.11 g (1.1 wt. %) of the powdered CNS flakes were mixed well using a wooden tongue depressor. SO7678 crosslinker (1 g) was then stirred into the mixture using a wooden tongue depressor. The addition of the crosslinker to the silanol-terminated PDSM/catalyst mixture causes the sample to cure quickly. Before cure was complete, the mixture was quickly sandwiched between a pair of steel plates with an appropriate steel spacer with a thickness of approximately 1 mm. The entire stack was placed into a Carver Laboratory Press (Model No. 3725, Wabash, Ind.). The press was used to apply a pressure of approximately 1 metric ton at room temperature for five minutes. The silicone composite sample was then removed from the plates and dried at room temperature for 1 hour.

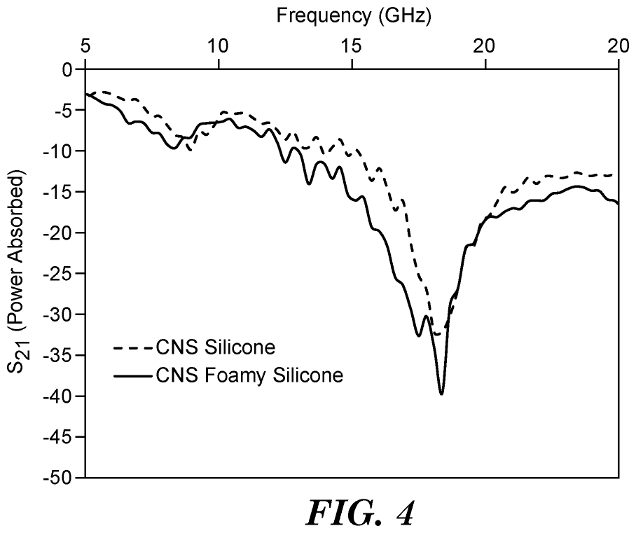

FIG. 4 reports test results for Comparative Example 1 and Example 1. As shown in FIG. 4, the composite with intrinsic porosity (Example 1) shows that the composites with intrinsic porosity made using the dehydrogenation chemistry show superior power absorption (3-8 dB improvement) in the 1-25 GHz range compared to the Comparative Example 1 which is a non-foamy composite even though both contain the same amount of active fillers (1.1 wt. % of the CNS material). This implies that absorber performance of the silicone composite with intrinsic porosity (Example 1) can be superior to the absorber performance of the composite without intrinsic porosity (Comparative Example 1), and thereby provide enhanced EMI absorber performance.

### Example 2

Example 1 was repeated, except that the silicone composite was prepared using 0.028 g (0.28 wt. %) CNS flakes and 2 g of SO7678.

All cited references, patents, and patent applications in the above application for letters patent are herein incorporated by reference in their entirety in a consistent manner. In the event of inconsistencies or contradictions between portions of the incorporated references and this application, the information in the preceding description shall control. The preceding description, given in order to enable one of ordinary skill in the art to practice the claimed disclosure, is not to be construed as limiting the scope of the disclosure, which is defined by the claims and all equivalents thereto.

1-13. (canceled)

14. An electronic article comprising an electronic component bonded to a composite composition, the composite composition comprising: a crosslinked silicone foam, wherein the crosslinked silicone foam has polydimethylsiloxane segments; and electromagnetically responsive particles, wherein the electromagnetically responsive particles are retained in the crosslinked silicone foam, wherein the composite composition is capable of absorbing at least a portion of incoming electromagnetic energy in a frequency range of 0.1 to 40 GHz, and wherein the electromagnetically responsive particles comprise a polymeric encapsulation material, and crosslinked multiwall carbon nanotube-based networks are fully encapsulated by the polymeric encapsulation material.

15. The electronic article of claim 14, wherein the electronic component comprises at least one of a processor, coprocessor, memory device, transistor, transmission line, optical interconnects or conductor.

16. The electronic article of claim 14, wherein the composite composition consists essentially of the crosslinked silicone foam and the electromagnetically responsive particles.

17. The electronic article of claim 1, wherein the composite composition further comprises inorganic oxide particles.

18. A composite composition comprising:
a crosslinked silicone foam, wherein the crosslinked silicone foam has polydimethylsiloxane segments; and
electromagnetically responsive particles retained in the crosslinked silicone foam, wherein the electromagnetically responsive particles comprise carbon nanotubes, wherein the composite composition is capable of absorbing at least a portion of incoming electromagnetic energy in a frequency range of 0.1 to 40 GHz, and wherein the electromagnetically responsive particles comprise a polymeric encapsulation material, and crosslinked multiwall carbon nanotube-based networks are fully encapsulated by the polymeric encapsulation material.

19. The composite composition of claim 18, wherein the composite composition comprises inorganic oxide particles.

20. The composite composition of claim 18, wherein the composite composition is molded according to a predetermined shape.

21. An electromagnetic wave shielding article comprising a composite composition according to claim 18 secured to a pressure-sensitive adhesive layer.

22. The electromagnetic wave shielding article of claim 21, further comprising a backing disposed between the composite composition and the pressure-sensitive adhesive layer.
